(19) United States
(12) Patent Application Publication
(10) Pub. No.: US 2006/0228834 A1
(43) Pub. Date: Oct. 12, 2006

(54) Fabrication method of image scan module

(75) Inventors: Pen-Jung Lee, Sindian City (TW); Ling-Ta Su, Sindian City (TW); Ming-Chieh Lin, Sindian City (TW)

Correspondence Address: HDSL, 4331 STEVENS BATTLE LANE, FAIRFAX, VA, 22033, US

(73) Assignee: CREATIVE SENSOR INC.

(21) Appl. No.: 11/102,674

(22) Filed: Apr. 11, 2005

(51) Int. Cl. H01L 21/339

(52) U.S. Cl. 438/144

(57) ABSTRACT

A method of fabricating a CCDM scan module applied for image scan. A circuit board on which electronic devices are mounted is provided. A photo-detector and an integrated circuit device which is either packaged or unpackaged are also mounted on the circuit board to form an image sensor board. The electric connection between the photo-detector, the IC devices and the circuit board is established by wire-bonding technique. A module base is provided, and at least one reflection mirror and one transmission lens are mounted on the module base at predetermined positions. The image sensor board is then mounted on the module base at a position aligned with the lens for focusing an image.

### BACKGROUND OF THE INVENTION

1. Field of Invention

The present invention relates in general to a fabrication method of an image scan module, and more particularly, to a fabrication method of image scan module of which the device assembly accuracy is improved, the fabrication steps are minimized, and the fabrication cost is reduced.

2. Related Art

The conventional method for fabricating a scan module applied to an image scanner is illustrated in FIG. 1. In addition to the fabrication of a circuit board, the photo-detector and an IC electronic device are mounted on a carrier board. Through individual package process, a deep-type or STM-type optical or electronic device is formed. After soldering process, the packaged photo-detector and IC electronic device are assembled on the circuit board to complete the fabrication of an image sensor board. The image sensor board is further assembled with reflection mirrors, transmission lens on a module base to form the scan module.

The assembly of photo-detector and the carrier board uses conventional package process to electrically connect the photo-detector and the carrier board. During assembly, a first assembly error or tolerance occurs. While assembling the carrier board carrying the photo-detector and the circuit board by soldering, the altitude and uniformity of the photo-detector assembly is difficult to control, and it is difficult to accurately align the photo-detector assembly with the transmission les. Thereby, a second assembly error or tolerance occurs. The second assembly error, which sometimes affects the image scanning effect, is typically more significant than the first assembly error. Therefore, screws or other mechanisms are often required in the latter assembly process to provide more accurate alignment. The complex assembly process is disadvantageous to mass production. In addition, additional carrier board is required for assembling the photo-detector and the IC electronic device, such that the dimension of the image sensor board is larger, and the fabrication cost for the image sensor board is higher.

### SUMMARY OF THE INVENTION

A fabrication method for an image scan module is provided, which uses chip-on-board (COB) and wire-bonding technique to directly mount the photo-detector and the packaged or unpackaged IC electronic device on the circuit board, and establish electric connection therebetween. Thereby, an image sensor board is integrally assembled. The image sensor board is then aligned with lenses and mirrors and mounted to a module base to perform optical image scanning, such that the assembly of the photo-detector is more accurate. The fabrication method as provided avoids the package process of conventional IC electronic device, and eliminate the requirement of the carrier board, package glass, plastic enclosure, such that the module volume is reduced, and the fabrication and assembly cost is reduced.

### BRIEF DESCRIPTION OF THE DRAWINGS

The present invention will become more fully understood from the detailed description given hereinbelow illustration only, and thus are not limitative of the present invention, and wherein:

FIG. 1 is a fabrication process of a conventional scan module;

FIG. 2 shows an embodiment of a fabrication process of a scan module provided by the present invention;

FIG. 3 is a structure diagram of an embodiment of an image sensor board; and

FIG. 4 shows another embodiment of a fabrication process for a scan module.

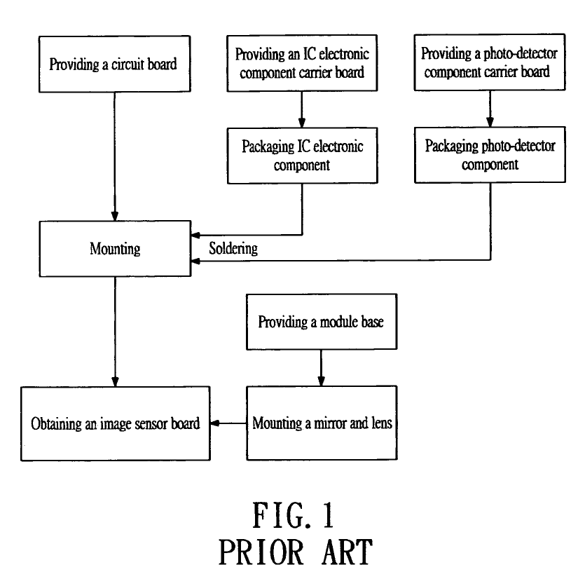

### DETAILED DESCRIPTION OF THE INVENTION

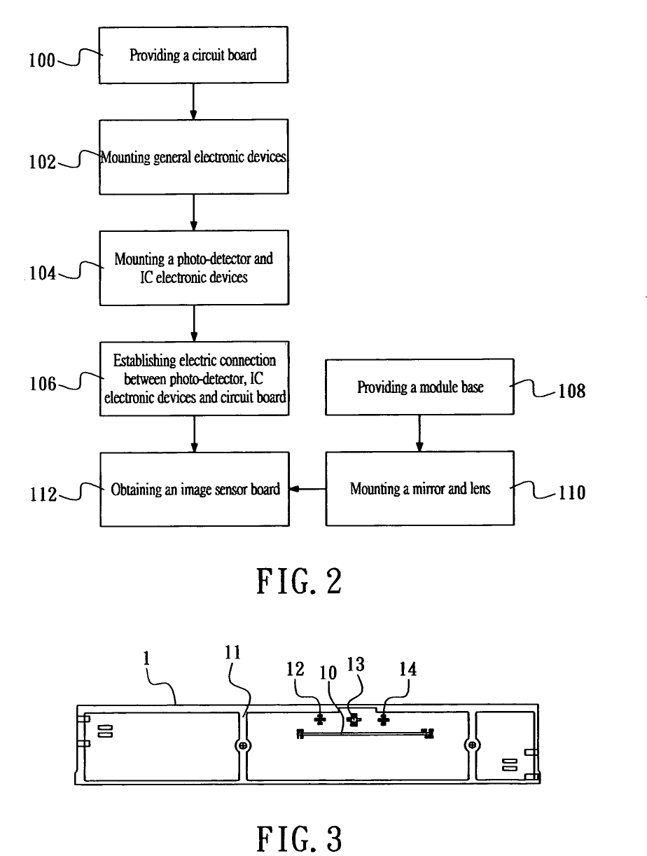

FIG. 2 shows an embodiment of a fabrication method of a scan module, including the following steps.

In step 100, a circuit board 11 for fabricating an image sensor board 1 is provided.

In step 102, electronic devices are mounted to the circuit board 11. The electronic devices include passive devices such as resistors, capacitors, and inductors. The electronic devices are electrically connected to the circuit board 11 by soldering, for example.

In step 104, a photo-detector 10 and IC electronic devices 12, 13 and 14 are mounted to the circuit board 11 by chip-on-board (COB) process, for example. The bare chip of the photo-detector 10 and the unpackaged IC electronic devices 12, 13 and 14 are bonded on the predetermined positions of the circuit board 11.

In step 106, the electric connection between the photo-detector 10, the IC electronic devices 12, 13, 14 and the circuit board 11 is established by wire bonding, and conductive wires such as gold wires are used for such connection. Thereby, an image sensor board 1 is formed as shown in FIG. 3.

In step 108, a module base is provided. The module base is fabricated by mold injection, for example, and positions for mounting the image sensor board 1, mirrors and lenses are predetermined.

In step 110, at least one mirror is mounted to the module base on which the mirror and lens are mounted

In step 112, the image sensor board 1 is assembled with the module base on which the mirror and the lens have been mounted.

In step 104, the photo-detector 10 mounted on the circuit board 11 includes a charge coupled device (CCD), complementary metal oxide semiconductor (CMOS) detector, for example.

In addition, in step 104, the IC electronic devices 12, 13 and 14 include buffer IC, logic IC and ADC chip used in the scan module, for example.

In the step 110, at least one mirror and lens are mounted on the predetermined positions of the module base before, during and after any of the steps 102, 104, and 106.

By the above process, the combination of COB technique and wire bonding technique directly mounts the photo-detector 10 and the IC electronic devices 12, 13, 14 on the circuit board 11 and establish the electric connection therebetween. Thereby, an image sensor board 1 is formed to directly assembled on the module base on which the lens and mirrors are already mounted on the predetermined positions. This eliminates the package process of the IC electronic device, the requirement of carrier board, package glass, plastic enclosure. Moreover, the over volume of the scan module is reduced, and the fabrication and assembly cost are reduced. Further, the photo-detector and the IC electronic devices can be mounted on the circuit board in the form of bare chips. Therefore, no screws or other assisting mechanism are required to adjust the alignment with the lens and mirrors. Therefore, the assembly accuracy is increased.

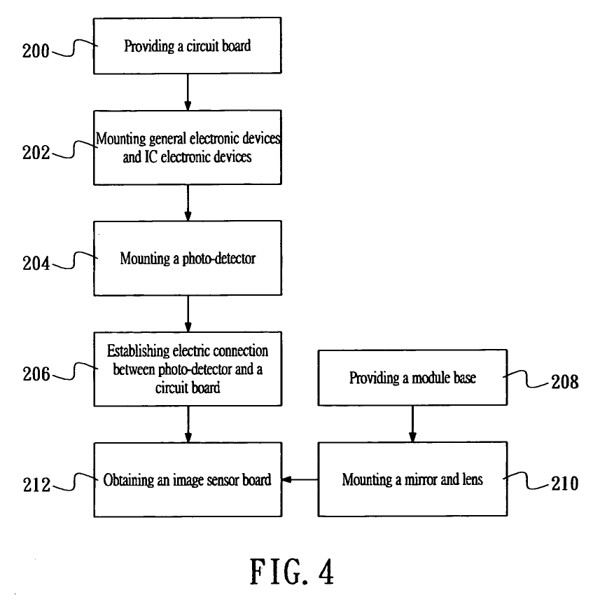

Referring to FIG. 4, another embodiment of fabrication method of a scan module is illustrated.

In step 200, a circuit board 11 used for forming an image sensor board 1 is provided.

In step 202, general electronic devices such as passive devices, including resistors, capacitors, and inductors, the unpackaged IC electronic devices 12, 13, 14 such as buffer IC, logic IC and ADC chips are mounted on the circuit board 11.

In step 204, the photo-detector 10 is mounted on the circuit board 11 by COB technique, for example. The photo-detector 10 is thus mounted to the predetermined position of the circuit board 11 in the form of bare chip.

In step 206, the electric connection between the photo-detector 10 and the circuit board 11 is established by wire bonding technique. Conductive wire such as gold wire is used for electrically connecting the photo-detector 10 to the circuit board 11, such that an image sensor board 1 is formed.

In step 208, a module base is provided. The module base is preferably formed by mold injection with predetermined positions of mirrors, lenses and the photo-detectors.

In step 210, at least one mirror and one lens are mounted to the predetermined positions.

In step 212, the image sensor board 1 is mounted on the module base.

According to the embodiment as shown in FIG. 4, the scan module applied for image scanning reduces photo-detector is fabricated with reduced volume, fabrication process and cost. In addition, the requirement of screw or other mechanism is eliminated, while the alignment accuracy between the photo-detector and the mirror and lens is enhanced.

The invention being thus described, it will be obvious that the same may be varied in many ways Such variations are not to be regarded as a departure from the spirit and scope of the invention, and all such modifications as would be obvious to one skilled in the art are intended to be included within the scope of the following claims.

What is claimed is:

1. A fabrication process of a scan module, applied as a fabrication process for a CCMD scan module for image scanning, comprising:
a. mounting a plurality of electronic devices on a circuit board;
b. mounting a photo-detector and at least one IC electronic device on the circuit board;
c. electronically connecting the photo-detector and the IC electronic device to the circuit board to form an image sensor board;
d. providing a module base on which at least one mirror and one lens are mounted; and
e. mounting the image sensor board to a predetermined position of the module base.

2. The method of claim 1, wherein the photo-detector and the IC electronic device are in the form of bare chips while being mounted to the circuit board.

3. The method of claim 1, wherein the photo-detector includes a CCD or a CMOS detector.

4. The method of claim 1, wherein the IC electronic device includes a buffer IC, a logic IC or an ADC chip.

5. The method of claim 1, wherein step b is performed before, during or after any of steps a, b and c.

6. A method of fabricating a scan module, comprising:
fabricating a circuit board, and mounting at least one passive electronic device and at least one IC electronic device on the circuit board;
mounting a photo-detector on the circuit board;
electrically connecting the photo-detector with the circuit board to form an image sensor board;
providing a module base, and mounting at least one mirror and one lens on the module base at predetermined positions; and
mounting the image sensor on the circuit board.

7. The method of claim 6, wherein the IC electronic device includes a packaged buffer IC, logic IC or ADC chip.

8. A fabrication method for an image sensor board of a scan module, comprising:
fabricating a circuit board, and mounting at least one electronic device and at least one IC electronic device on the circuit board;
mounting a photo-detector on the circuit board; and
electrically connecting the photo-detector to the circuit board for forming an image sensor board.

9. The method of claim 8, further comprising electrically connecting the photo-detector with the electronic device and the IC electronic device.
